(19) United States
(12) Patent Application Publication
(10) Pub. No.: US 2021/0320048 A1
(43) Pub. Date: Oct. 14, 2021

(54) COLD PLATE WITH INTEGRATED VAPOR CHAMBER

(71) Applicant: Intel Corporation, Santa Clara, CA (US)

(72) Inventors: Ameya Limaye, Portland, OR (US); Evan A. Chenelly, Albion, NY (US)

(73) Assignee: Intel Corporation, Santa Clara, CA (US)

(21) Appl. No.: 17/357,792

(22) Filed: Jun. 24, 2021

(51) Int. Cl. H01L 23/427; H01L 23/473; H01L 25/065; H01L 25/10

(52) U.S. Cl. CPC H01L 23/427; H01L 25/105; H01L 25/0655; H01L 23/473

(57) ABSTRACT

A cold plate with an integrated vapor chamber allows for improved temperature equalization across integrated circuit dies in an integrated circuit component. The cold plate comprises a first chamber and a vapor chamber that share a common inner wall. The cold plate is attached to an integrated circuit component positioned adjacent to the vapor chamber. Heat generated by integrated circuit dies is transferred to the vapor chamber where it is absorbed by a two-phase working fluid as latent heat. Heat is removed from the vapor chamber by a cooling liquid flowing through the cold plate absorbing heat ejected from the working fluid as it condenses. The heated cooling liquid exits the cold plate at a fluid outlet. Cold plates with integrated vapor chambers can be used to equalize temperatures across multiple integrated circuit components in a similar fashion.

### BACKGROUND

An integrated circuit component can be liquid-cooled by a cold plate that is attached to the integrated circuit component. Cooling liquid enters the cold plate at a fluid input, absorbs heat generated by the integrated circuit component as it flows through the cold plate, and exits the cold plate as heated cooling liquid at a fluid output.

### BRIEF DESCRIPTION OF THE DRAWINGS

FIG. 1A illustrates a cross-sectional view of an example cold plate with an integrated vapor chamber attached to an integrated circuit component.

FIG. 1B illustrates a top view of the example cold plate with an integrated vapor chamber and integrated circuit component of FIG. 1A.

FIG. 2 is a graph illustrating example temperatures for integrated circuit dies under operation and attached to two different types of cold plates.

FIG. 3A illustrates a cross-sectional view of an example cold plate with an integrated vapor chamber attached to multiple integrated circuit components.

FIG. 3B illustrates a top view of the example cold plate with an integrated vapor chamber and integrated circuit components of FIG. 3A.

FIG. 4 is an example method of operating a computing system comprising an integrated circuit component and a thermal management solution comprising a cold plate with an integrated vapor chamber.

FIG. 5 is a block diagram of an exemplary computing system in which technologies described herein may be implemented.

FIG. 6 is a block diagram of an exemplary processor unit that can execute instructions as part of implementing technologies described herein.

### DETAILED DESCRIPTION

Liquid cooling of integrated circuit components via cold plates can result in the uneven cooling of integrated circuit dies located within the integrated circuit component. As a cooling liquid flows through a cold plate it absorbs heat generated by the integrated circuit dies within the integrated circuit component. Dies located downstream in the direction of cooling liquid flow from other dies in the integrated circuit component are cooled by a cooling liquid that has been preheated by dies located upstream, resulting in the cooling liquid having a reduced capacity to cool the downstream dies. This cooling liquid preheating can result in an unequal distribution of temperatures across the integrated circuit dies in the integrated circuit component during operation, with downstream dies having greater temperatures than upstream dies. The downstream dies can thus limit the thermal design power (TDP) of the integrated circuit component. Similarly, when multiple integrated circuit components are liquid-cooled in series, downstream components are cooled by a cooling liquid that has been preheated by upstream components. As a result, downstream integrated circuit components can limit the TDP limiter of a computing system.

The cold plates with integrated vapor chambers (CPVCs) disclosed herein, which can be alternatively referred to herein as a cooling apparatuses, comprising an integrated vapor chamber can provide a more equalized distribution of temperatures across components being liquid-cooled (e.g., multiple integrated circuit dies within an integrated circuit component, multiple integrated circuit components). Heat generated by the integrated circuit component is captured as latent heat by an evaporating two-phase working fluid located in a vapor chamber. Evaporated working fluid condenses at the interface between a first chamber and a vapor chamber and cooling liquid flowing through the first chamber absorbs heat from the working fluid. The cold plates with integrated vapor chambers described herein can provide a more equalized distribution of temperatures across upstream and downstream integrated circuit dies or components since the heat generated by the dies or components is captured through evaporation of a two-phase fluid occupying a vapor chamber whose lateral boundary that encompasses the outer boundaries of the elements being cooled as opposed to generated heat being directly transferred to the cooling liquid flowing through the cold plate.

The CPVCs disclosed herein can provide at least the following advantages. First, they can provide for improved temperature equalization between upstream and downstream integrated circuit dies (or integrated circuit components), thereby lowering the temperature of the dies (or components) that may be limiting the TDP of the integrated circuit component (or computing system) and allow for integrated circuit components (or computing systems) to run cooler. Second, a computing device employing the disclosed CPVCs may not be subject to the physical design constraints of having to avoid placing liquid-cooled integrated circuit dies or components located downstream from one another. The removal of these shadowing physical design constraints may give integrated circuit component and computing system designers more flexibility. Third, the CPVCs disclosed herein can be used with existing liquid cooling infrastructure.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, reference to integrated circuit dies or integrated circuit components that have substantially equalized temperatures includes integrated circuit dies or integrated circuit components that have temperatures within a few degrees of each other.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

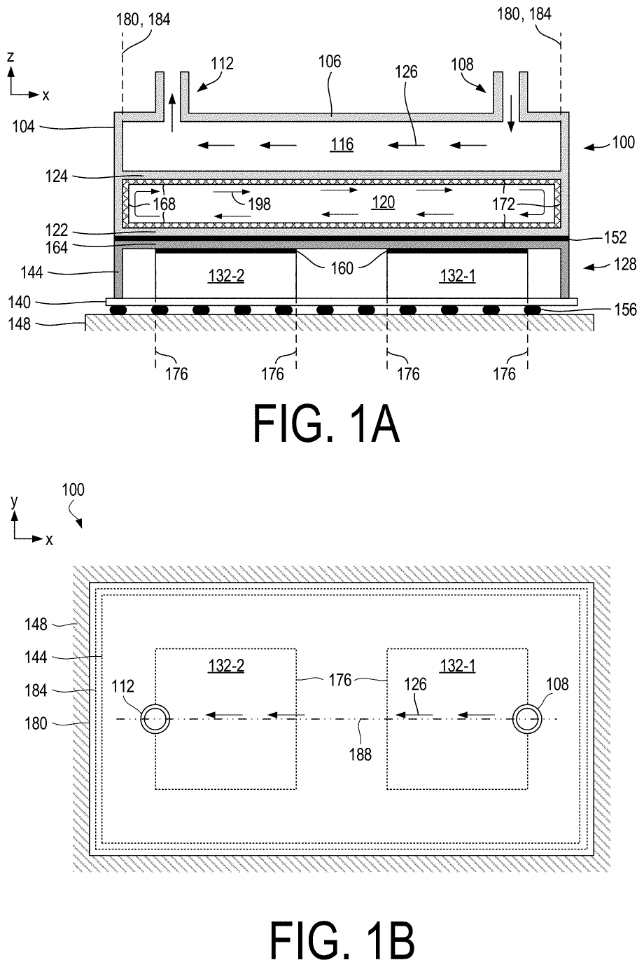

FIG. 1A illustrates a cross-sectional view of an example cold plate with an integrated vapor chamber attached to an integrated circuit component. The CPVC 100 comprises a casing 104, a fluid input 108, a fluid output 112, a first chamber 116, and a vapor chamber 120. The casing 104 comprises a first wall 106 and a second wall 122. The CPVC 100 further comprises an inner wall 124. The first chamber 116 is connected to the fluid input 108 and the fluid output 112 and is enclosed in part by the first wall 106 and the inner wall 124. The vapor chamber 102 is enclosed in part by the inner wall 124 and the second wall 122. The inner wall 124 is common to the first chamber 116 and the vapor chamber 120. During operating of a computing system within which the CPVC 100 is located, a cooling liquid flows through the first chamber 116 from the fluid input 108 to the fluid output 112 in a direction indicated by arrows 126. The cooling liquid of any CPVC described herein can be water, deionized water, a glycol/water solution, a dielectric fluid such as fluorocarbons or polyalphaolefin (PAO), or other suitable material. The vapor chamber 120 comprises a working fluid. The working fluid used in any of the vapor chambers described herein can be a two-phase working fluid, such as water, ammonia, methanol, refrigerants, ethanol, or other suitable material. Any of the CPVCs disclosed herein can comprise a first chamber of any suitable type, such as a tubed first chamber or a first chamber comprising internal fins or channels (e.g., microchannels). A CPVC can be made of any suitable material, such as copper, aluminum, or stainless steel that is chemically compatible with immersion and working fluids. In some embodiments, at least the second wall 122 and the inner wall 124 are made of aluminum, copper, or other suitable thermally conductive material.

In some embodiments, the CPVC 100 is a single physical component. That is, the CPVC 100 does not comprise components that are releasably attached by, for example, a TIM layer. In some embodiments, the CPVC 100 may comprise multiple components that have been securely attached by, for example, soldering. Thus, the inner wall 124 can be a single wall of thermally conductive material or it can comprise multiple walls of thermally conductive materials that have been securely attached by, for example, soldering or other suitable attachment that provides the first chamber 116 to be thermally coupled to the vapor chamber 120. As used herein, the term “thermally coupled” refers to components that are coupled to facilitate the transfer of heat between them.

The CPVC 100 is attached to an integrated circuit component 128 that is positioned adjacent to the vapor chamber 120. The integrated circuit component 128 comprises integrated circuit dies 132 (132-1, 132-2), a substrate 140, and a casing 144. The integrated circuit component 128 is attached to a printed circuit board 148 by solder balls or solder bumps 156. In other embodiments, the integrated circuit component 128 can be attached to the printed circuit board 148 via a socket. The CPVC 100 is attached to the integrated circuit component 128 by a thermal interface material (TIM) layer 152. TIM layers 160 thermally couple the integrated circuit dies 132 to the casing 144. The portion of the casing 144 between the TIM layers 152 and 160 is a thermally conductive material, such as aluminum or copper. Any TIM layer described herein, such as TIM layers 152 or 160 can comprise a silver thermal compound, thermal grease, phase change materials, indium foils, graphite sheets, or other suitable material. In some embodiments, the casing 144 or at least a portion of the casing 144 between the TIM layers 152 and 160 comprises an integrated heat spreader.

As used herein, the term “integrated circuit component” refers to a packaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

FIG. 1B illustrates a top view of the example cold plate with integrated vapor chamber and integrated circuit component of FIG. 1A. A lateral boundary 180 of the vapor chamber 120 and a lateral boundary 184 of the first chamber 116 encompass outer boundaries 176 of the integrated circuit dies 132. The lateral boundaries 180 and 184 are the physical extents of the vapor chambers 120 and first chamber 116, respectively, in the x and y dimensions, as those dimensions are indicated in FIG. 1B. It is to be noted that the lateral boundaries 180 and 184 are shown as having the same extent in FIG. 1A and having different extents in FIG. 1B. This is to illustrate that the first chamber 116 and the vapor chamber 120 can have the same area and be aligned in some embodiments and be of different sizes and not aligned in others. In some embodiments, the first chamber 116 may not encompass the outer boundaries 176 of the integrated circuit components 132.

The integrated circuit dies 132 are arranged along an axis 188 extending from the fluid input 108 to the fluid output 112 with the integrated circuit die 132-2 being downstream from the integrated circuit die 132-1 with regard to the direction of flow of the cooling liquid through the CPVC 100, as indicated by the arrows 126. That is, the die 132-2 is located further along the axis 188 from the fluid input 108 than the die 132-1.

Although the integrated circuit component 128 is illustrated as having only two integrated circuit dies 132, in other embodiments, the integrated circuit component 128 can have more than two integrated circuit dies. In these embodiments, more than two integrated circuit dies can be arranged along the axis 188. Although FIG. 1B shows integrated circuit components 128 centered about the axis 188, it is not necessary that an integrated circuit component attached to the CPVC 100 be centered about the axis 388. Further, in some embodiments, the integrated circuit dies 132 can have different sizes. Moreover, in some embodiments, the integrated circuit component 128 can comprise integrated circuit dies of different types, such as various types of processing units (e.g., CPUs, GPUs), voltage regulators, and memories. Furthermore, the integrated circuit dies within an integrated circuit component can be capable of operating at different power consumption levels (e.g., different supply voltages, operating frequencies, operational states (e.g., active, sleep, turbo states)). Thus, the CPVCs described herein can be used to equalize temperatures for integrated circuit dies in an integrated circuit component varying in size, physical arrangement, type, count, and power consumption levels.

The CPVC 100 dissipates heat generated during operation of the integrated component 128 as follows. Heat generated by the integrated circuit dies 132 flows through the TIM layer 160s, the casing 144, the CPVC second wall 122 and into the vapor chamber 120, where it is absorbed as latent heat by the working fluid. Evaporated working fluid rises within the vapor chamber 120 to the inner wall 124. Heat is transferred from the vapor chamber 120 to the first chamber 116 by heat flowing from evaporated working fluid through the inner wall 124 where it is absorbed by the cooling liquid flowing through the first chamber 116. The heat absorbed by the cooling liquid is removed from the CPVC 100 by the heated cooling liquid flowing out of the first chamber 116 through the fluid output 112.

As the working fluid condenses at the interface between the vapor chamber 120 and the inner wall 124 due to the release of its latent heat, the condensed working fluid returns to the bottom of the vapor chamber 320 (the portion of the vapor chamber adjacent to the second wall 122). The arrows 198 illustrate a path that the working fluid can flow in the vapor chamber 120 in some embodiments. In some embodiments, the return of condensed working fluid from the interface between the vapor chamber 120 and the inner wall 124 to the bottom of the vapor chamber 120 can be aided by one or more wicks 168 located along one or more faces 172 of the vapor chamber. Any of the wicks described herein can comprise sintered copper powder, copper fibers (which, in some embodiments, can be woven into forms such as a screen, mesh, or braids), or grooves integrated into a face of a vapor chamber.

The presence of an integrated vapor chamber 120 in the CPVC 100 provides for improved temperature equalization of the integrated circuit dies 132 due to the lateral boundary 180 of the vapor chamber 120 encompassing the outer boundaries of the integrated circuit dies 132. Heat absorbed by the working fluid in a region of the vapor chamber 120 above either of integrated circuit dies 132 will be distributed to other regions of the vapor chamber 120 due to thermal diffusion. Thus, heat absorbed by the working fluid in a region of the vapor chamber 120 above the die 132-1 can be distributed to regions of the vapor chamber 120 above the 131-2 and heat absorbed by the working fluid in a region of the vapor chamber 120 above the die 132-2 can be distributed to regions of the vapor chamber 120 above the die 132-1. By being constrained to a confined space (the vapor chamber 120), the working fluid is less capable of supporting the thermal gradients that can exist in the cooling liquid flowing through the first chamber 116. Thermal diffusion provides the negative feedback that prevents thermal gradients from developing in the working fluid. That is, the more that thermal gradients develop in the working fluid, the more that heat flows from hotter regions to cooler regions in the vapor chamber 120. This can result in a more equal temperature distribution in the working fluid (and thus, the integrated circuit dies 132) relative to that in a thermal management solution comprising a cold plate without an integrated vapor chamber.

The temperatures of the integrated circuit dies 132 during operation are substantially equalized. That is, the integrated circuit dies 132 may have temperatures during operation that are within several degrees of each other. This amount of integrated circuit die temperature equalization may be better than that provided by a thermal management solution wherein a cold plate without an integrated vapor chamber is attached to an integrated circuit component and downstream die are provided with a lesser degree of cooling by the cooling liquid due to the cooling liquid being preheated by upstream dies.

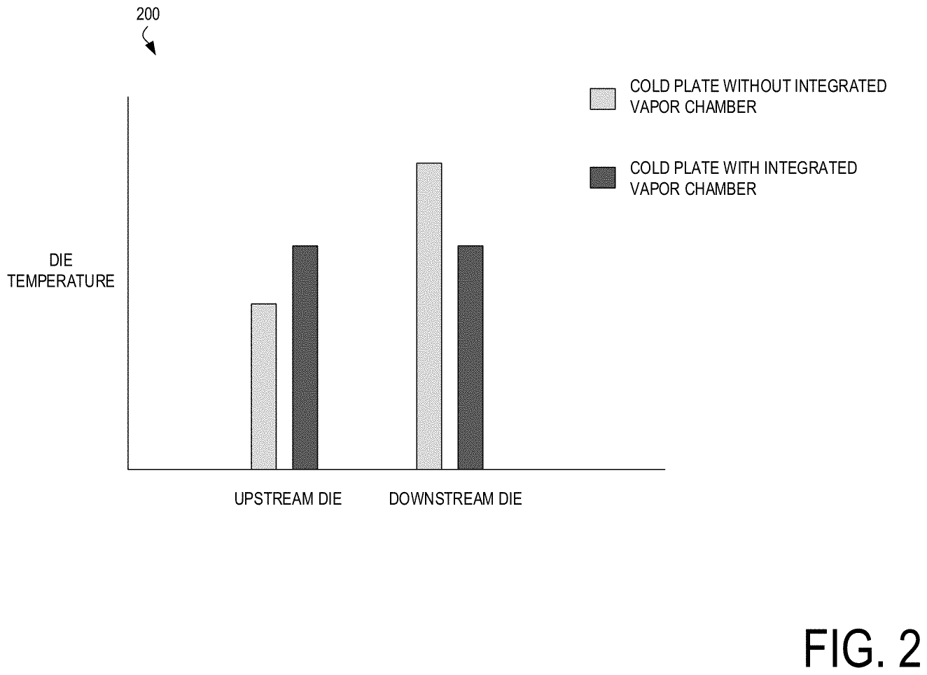

FIG. 2 is a graph illustrating example temperatures for integrated circuit dies under operation and attached to two different types of cold plates. The graph 200 illustrates qualitative differences in integrated circuit die temperatures for two different thermal management approaches—attaching an integrated circuit component to a cold plate without an integrated vapor chamber and attaching the integrated circuit component to a cold plate with an integrated vapor chamber. The qualitative temperature differences illustrated in the graph 200 are based on finite element analysis simulation results. As can be seen, the temperature difference between the upstream die and the downstream die is much larger when a cold plate without an integrated vapor chamber is used as the thermal management solution. When a cold plate with an integrated vapor chamber is used, the integrated circuit die temperatures are more equalized.

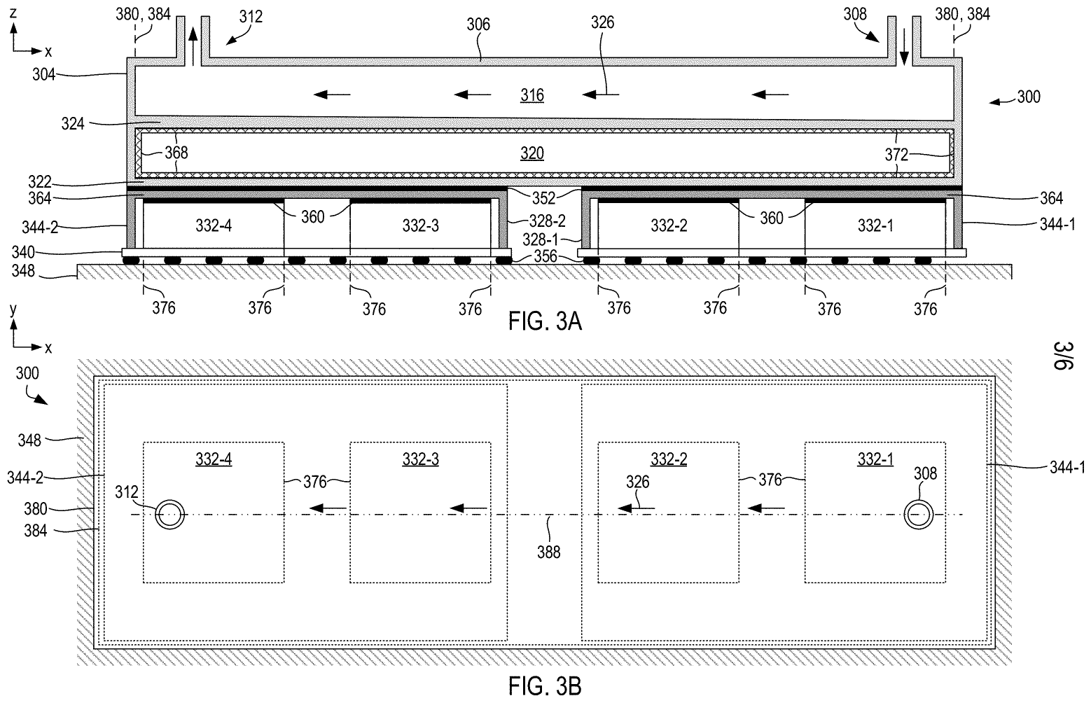

In some embodiments, cold plates with integrated vapor chambers can be used to equalize the temperature of multiple integrated circuit components. FIG. 3A illustrates a cross-sectional view of an example cold plate with an integrated vapor chamber attached to multiple integrated circuit components positioned adjacent to the vapor chamber. The CPVC 300 comprises a casing 304, a fluid input 308, a fluid output 312, a first chamber 316, and a vapor chamber 320. The casing 304 comprises a first wall 306 and a second wall 322. The CPVC 300 further comprises an inner wall 324. The first chamber 316 is connected to the fluid input 308 and the fluid output 312 and is enclosed in part by the first wall 306 and the inner wall 324. The vapor chamber 320 is enclosed in part by the inner wall 324 and the second wall 322. The inner wall 324 is common to the first chamber 316 and the vapor chamber 320. During the operation of a computing system within which the CPVC 300 is located, a cooling liquid flows through the first chamber 316 from the fluid input 308 to the fluid output 312 in a direction indicated by arrows 326. The vapor chamber 320 comprises a working fluid. In some embodiments, at least the second wall 322 and the second wall 324 are made of aluminum, copper, or other suitable thermally conductive material.

In some embodiments, the cold plate with integrated vapor chamber 300 is a single physical component. That is, the CPVC 300 does not comprise components that are releasably attached by, for example, a TIM layer. In some embodiments, the CPVC 300 may comprise multiple components that have been securely attached by, for example, soldering. Thus, the wall 324 can be a single wall of thermally conductive material or it can comprise multiple walls of thermally conductive materials that have been securely attached by, for example, soldering or other suitable attachment that provides for the first chamber 116 to be thermally coupled to the vapor chamber 320.

The CPVC 300 is attached to integrated circuit components 328 (328-1, 328-2) positioned adjacent to the vapor chamber 320. The integrated circuit component 328-1 comprises integrated circuit dies 332-1 and 332-2 and integrated circuit component 328-2 comprises integrated circuit dies 332-3 and 332-4. The integrated circuit components 328 comprise a substrate 340 and a casing 344. The integrated circuit components 328 are attached to a printed circuit board 348 by solder balls or solder bumps 356. The CPVC 300 is attached to the integrated circuit components 328 by thermal interface material (TIM) layers 352. TIM layers 360 thermally couple the integrated circuit dies 332 to their respective casings 344. The portions of the casings 344 between the TIM layers 352 and 360 comprise a thermally conductive material, such as aluminum or copper. In some embodiments, the casings 344 or at least a portion of the casings 344 between the TIM layers 352 and 360 comprise an integrated heat spreader.

FIG. 3B illustrates a top view of the example cold plate with an integrated vapor chamber and integrated circuit components of FIG. 3A. A lateral boundary 380 of the vapor chamber 320 and a lateral boundary 384 of the first chamber 316 encompass outer boundaries 376 of the integrated circuit components 332. As with the boundaries illustrated in FIGS. 1A and 1B, it is to be noted that the lateral boundaries 380 and 384 are shown as having the same extent in FIG. 3A and having different extents in FIG. 3B. This is to illustrate that the first chamber 316 and the vapor chamber 320 can have the same area and be aligned in some embodiments and be of different sizes and not aligned in others. In some embodiments, the first chamber 316 may not encompass the outer boundaries 376 of the integrated circuit components 332.

The integrated circuit components 328 are arranged along an axis 388 extending from the fluid input 308 to the fluid output 312 with integrated circuit component 328-2 being downstream from the integrated circuit component 328-1 with regard to the direction of flow of the cooling liquid through the CPVC 300, as indicated by the arrows 326. That is, the component 328-2 is located further along the axis 388 from the fluid input 308 than the component 328-1.

Although two integrated circuit components 328 are illustrated as being attached to the CPVC 300, in other embodiments, more than two integrated circuit components can be attached to the CPVC 300. In these embodiments, more than two integrated circuit components can be arranged along the axis 388. Although FIG. 3B shows integrated circuit components 328 centered about the axis 388, it is not necessary that an integrated circuit component attached to the CPVC 300 be centered about the axis 388. Further, integrated circuit components of different sizes can be attached to the CPVC 300. Moreover, the individual integrated circuit components attached to the CPVC 300 can comprise integrated circuit dies that vary in number, count, type, size, and/or power consumption levels from the integrated circuit dies in other integrated circuit components attached to the CPVC 300. Furthermore, in some embodiments, one or more passive electronic components (e.g., resistors, capacitors, inductors) can be attached to the CPVC 300 in addition to the integrated circuit components 328. The lateral boundary 380 of the vapor chamber 320 can encompass the outer boundary of the individual passive electronic components and temperatures of the attached passive electronic components can be equalized with those of the integrated circuit components 328.

The CPVC 300 dissipates heat generated during operation of the multiple integrated circuit components 328 in a manner similar to that described above for how the CPVC 100 dissipates heat generated by the integrated circuit dies 132. Heat generated by the integrated circuit dies 332 flows through the TIM layers 360, the casings 344, the CPVC second wall 322 and into the vapor chamber 320, where it is absorbed as latent heat by the working fluid. Evaporated working fluid rises within the vapor chamber 320 to the inner wall 324. Heat is transferred from the vapor chamber 320 to the first chamber 316 by heat flowing from evaporated working fluid through the wall 324 where it is absorbed by the cooling liquid flowing through the first chamber 316. The heat absorbed by the cooling liquid is removed from the CPVC 300 by the heated cooling liquid flowing out of the first chamber 316 through the fluid output 312.

As the working fluid condenses at the interface between the vapor chamber 320 and the inner wall 324 due to the release of its latent heat, the condensed working fluid returns to the bottom of the vapor chamber 320 (the portion of the vapor chamber 320 adjacent to the second wall 322). In some embodiments, the return of condensed working fluid to the bottom of the vapor chamber can be aided by one or more wicks 368 located along one or more faces 372 of the vapor chamber.

The presence of the integrated vapor chamber 320 in the CPVC 300 provides for improved temperature equalization of the integrated circuit components 328 due to the lateral boundary 380 of the vapor chamber 320 encompassing the outer boundaries of the integrated circuit components 328. Heat absorbed by the working fluid in a region of the vapor chamber 320 above either of integrated circuit components 328 will be distributed to other regions of the vapor chamber 320 due to thermal diffusion. Thus, heat absorbed by the working fluid in a region of the vapor chamber 320 above the component 328-1 can be distributed to regions of the vapor chamber 320 above the component 328-2 and heat absorbed by the working fluid in a region of the vapor chamber 320 above the component 328-2 can be distributed to regions of the vapor chamber 320 above the component 328-1. By being constrained to a confined space (the vapor chamber 320), the working fluid is less capable of supporting the thermal gradients that can exist in a cooling liquid flowing through the first chamber 316, for reasons similar to those as described above in regard to FIGS. 1A & 1B.

The temperatures of the integrated circuit components 328 during operation are substantially equalized. That is, the integrated circuit components 328 may have temperatures during operation that are within several degrees of each other. This amount of integrated circuit component temperature equalization may be better than that provided by a thermal management solution wherein a cold plate without an integrated vapor chamber is attached to multiple integrated circuit components and downstream components are provided with a lesser degree of cooling by the cooling liquid due to the cooling liquid being preheated by upstream components.

In embodiments where a cold plate with an integrated vapor chamber is part of a thermal management solution, the thermal management solution can further comprise a heat exchanger, pump, and one or more conduits (e.g., metal tubes) that create a loop that connects the CPVC, heat exchanger, and pump. The pump circulates a cooling liquid through the loop and the heat exchanger cools the cooling liquid that has been heated by integrated circuit components as it flows through the CPVC before the pump returns the cooling liquid to the CPVC to be heated again. In some embodiments, the heat exchanger, pump, and conduits reside within a single housing, such as in a stand-alone computing system (e.g., personal computer, server, or workstation), or a rack-level (e.g., blade, tray, blade) computing solution (e.g., rack server, hyper-converged infrastructure (HCl) server). In some embodiments, the heat exchanger and pump are located external to the housing in which the one or more integrated circuit components and cold plate with integrated vapor chamber are located, such as in a rack system wherein the heat exchanger and pump are part of the thermal management solution for multiple sleds, blades, or trays within a rack or across racks.

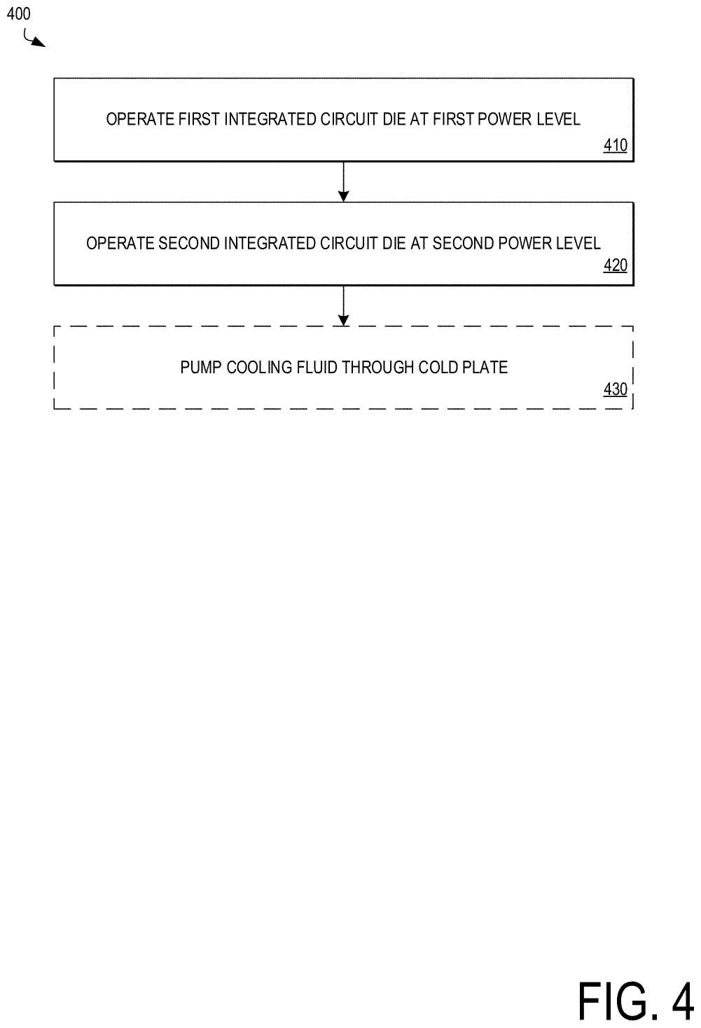

FIG. 4 is an example method of operating a computing system comprising an integrated circuit component and a thermal management solution comprising a cold plate with an integrated vapor chamber. The method 400 could be performed by, for example, a rack server comprising cold plate with an integrated vapor chamber attached to a server processor. At 410, a first integrated circuit die of a plurality of integrated circuit dies is operated at a first power consumption level. At 420, a second integrated circuit die of the integrated circuit dies is operated at a second power consumption level. The integrated circuit dies are located within an integrated circuit component attached to a CPVC. The CPVC comprises: a casing comprising a first wall, an inner wall, and a second wall, the integrated circuit component attached to the second wall; a fluid input; a fluid output; a first chamber connected to the fluid input and the fluid output, the first chamber enclosed in part by the first wall and the inner wall; and a vapor chamber comprising a two-phase fluid, the vapor chamber enclosed in part by the inner wall and the second wall. The method 400 can optionally include additional elements, such as pumping a cooling liquid through the CPVC at 430.

The CPVCs disclosed herein can be implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

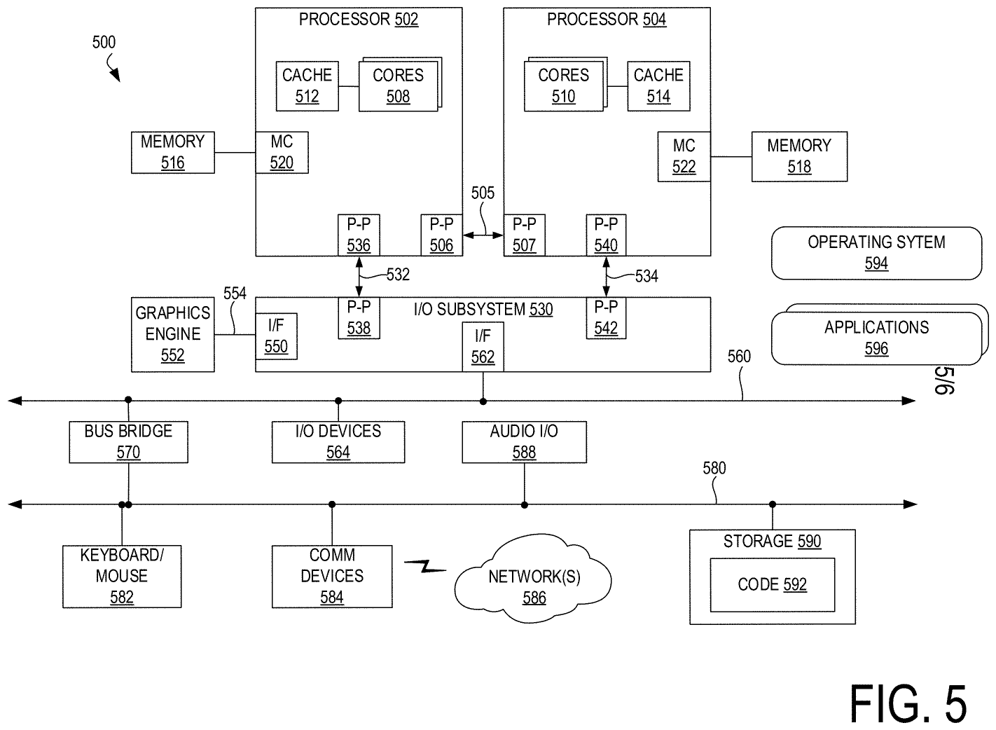

FIG. 5 is a block diagram of an exemplary computing system in which technologies described herein may be implemented. Generally, components shown in FIG. 5 can communicate with other shown components, although not all connections are shown, for ease of illustration. The computing system 500 is a multiprocessor system comprising a first processor unit 502 and a second processor unit 504 comprising point-to-point (P-P) interconnects. A point-to-point (P-P) interface 506 of the processor unit 502 is coupled to a point-to-point interface 507 of the processor unit 504 via a point-to-point interconnection 505. It is to be understood that any or all of the point-to-point interconnects illustrated in FIG. 5 can be alternatively implemented as a multi-drop bus, and that any or all buses illustrated in FIG. 5 could be replaced by point-to-point interconnects.

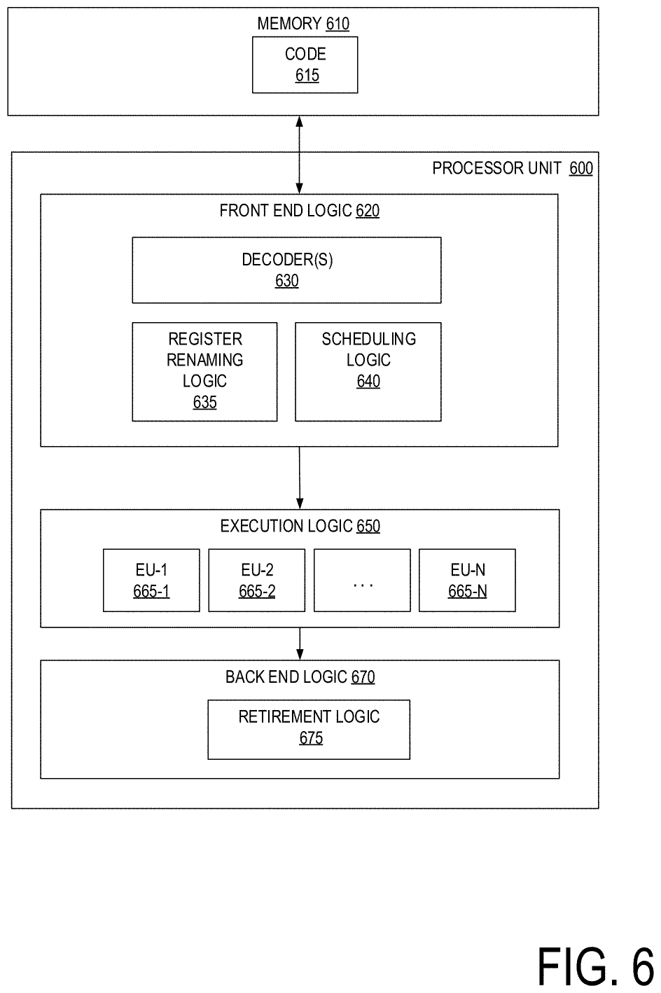

The processor units 502 and 504 comprise multiple processor cores. Processor unit 502 comprises processor cores 508 and processor unit 504 comprises processor cores 510. Processor cores 508 and 510 can execute computer-executable instructions in a manner similar to that discussed below in connection with FIG. 6, or other manners.

Processor units 502 and 504 further comprise cache memories 512 and 514, respectively. The cache memories 512 and 514 can store data (e.g., instructions) utilized by one or more components of the processor units 502 and 504, such as the processor cores 508 and 510. The cache memories 512 and 514 can be part of a memory hierarchy for the computing system 500. For example, the cache memories 512 can locally store data that is also stored in a memory 516 to allow for faster access to the data by the processor unit 502. In some embodiments, the cache memories 512 and 514 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 500 is shown with two processor units, the computing system 500 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 500 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 502 and 504 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 502 and 504 further comprise memory controller logic (MC) 520 and 522. As shown in FIG. 5, MCs 520 and 522 control memories 516 and 518 coupled to the processor units 502 and 504, respectively. The memories 516 and 518 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 520 and 522 are illustrated as being integrated into the processor units 502 and 504, in alternative embodiments, the MCs can be external to a processor unit.

Processor units 502 and 504 are coupled to an Input/Output (I/O) subsystem 530 via point-to-point interconnections 532 and 534. The point-to-point interconnection 532 connects a point-to-point interface 536 of the processor unit 502 with a point-to-point interface 538 of the I/O subsystem 530, and the point-to-point interconnection 534 connects a point-to-point interface 540 of the processor unit 504 with a point-to-point interface 542 of the I/O subsystem 530. Input/Output subsystem 530 further includes an interface 550 to couple the I/O subsystem 530 to a graphics engine 552. The I/O subsystem 530 and the graphics engine 552 are coupled via a bus 554.

The Input/Output subsystem 530 is further coupled to a first bus 560 via an interface 562. The first bus 560 can be a Peripheral Component Interconnect Express (PCIe) bus or any other type of bus. Various I/O devices 564 can be coupled to the first bus 560. A bus bridge 570 can couple the first bus 560 to a second bus 580. In some embodiments, the second bus 580 can be a low pin count (LPC) bus. Various devices can be coupled to the second bus 580 including, for example, a keyboard/mouse 582, audio I/O devices 588, and a storage device 590, such as a hard disk drive, solid-state drive, or another storage device for storing computer-executable instructions (code) 592 or data. The code 592 can comprise computer-executable instructions for performing methods described herein. Additional components that can be coupled to the second bus 580 include communication device(s) 584, which can provide for communication between the computing system 500 and one or more wired or wireless networks 586 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 502.11 standard and its supplements).

In embodiments where the communication devices 584 support wireless communication, the communication devices 584 can comprise wireless communication components coupled to one or more antennas to support communication between the computing system 500 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 500 can comprise removable memory such as flash memory cards (e.g., SD (Secure Digital) cards), memory sticks, Subscriber Identity Module (SIM) cards). The memory in system 500 (including caches 512 and 514, memories 516 and 518, and storage device 590) can store data and/or computer-executable instructions for executing an operating system 594 and application programs 596. Example data includes web pages, text messages, images, sound files, and video data to be sent to and/or received from one or more network servers or other devices by the system 500 via the one or more wired or wireless networks 586, or for use by the system 500. The system 500 can also have access to external memory or storage (not shown) such as external hard drives or cloud-based storage.

The operating system 594 can control the allocation and usage of the components illustrated in FIG. 5 and support the one or more application programs 596. The application programs 596 can include common computing system applications (e.g., email applications, calendars, contact managers, web browsers, messaging applications) as well as other computing applications.

In some embodiments, a hypervisor (or virtual machine manager) operates on the operating system 594 and the application programs 596 operate within one or more virtual machines operating on the hypervisor. In these embodiments, the hypervisor is a type-2 or hosted hypervisor as it is running on the operating system 594. In other hypervisor-based embodiments, the hypervisor is a type-1 or “bare-metal” hypervisor that runs directly on the platform resources of the computing system 594 without an intervening operating system layer.

In some embodiments, the applications 596 can operate within one or more containers. A container is a running instance of a container image, which is a package of binary images for one or more of the applications 596 and any libraries, configuration settings, and any other information that one or more applications 596 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 594. An orchestrator can be responsible for management of the computing system 500 and various container-related tasks such as deploying container images to the computing system 594, monitoring the performance of deployed containers, and monitoring the utilization of the resources of the computing system 594.

The computing system 500 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the system 500. External input and output devices can communicate with the system 500 via wired or wireless connections.

The system 500 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 500 can further comprise one or more additional antennas coupled to one or more additional receivers, transmitters, and/or transceivers to enable additional functions.

In addition to those already discussed, integrated circuit components, integrated circuit constituent components, and other components in the computing system 594 can communicate with interconnect technologies such as Intel® QuickPath Interconnect (QPI), Intel® Ultra Path Interconnect (UPI), Computer Express Link (CXL), cache coherent interconnect for accelerators (CCIX®), serializer/deserializer (SERDES), Nvidia® NVLink, ARM Infinity Link, Gen-Z, or Open Coherent Accelerator Processor Interface (OpenCAPI). Other interconnect technologies may be used and a computing system 594 may utilize more or more interconnect technologies.

It is to be understood that FIG. 5 illustrates only one example computing system architecture. Computing systems based on alternative architectures can be used to implement technologies described herein. For example, instead of the processors 502 and 504 and the graphics engine 552 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 5. Moreover, the illustrated components in FIG. 5 are not required or all-inclusive, as shown components can be removed and other components added in alternative embodiments.

FIG. 6 is a block diagram of an exemplary processor unit that can execute instructions as part of implementing technologies described herein. The processor unit 600 can be a single-threaded core or a multithreaded core in that it may include more than one hardware thread context (or “logical processor”) per processor unit.

FIG. 6 also illustrates a memory 610 coupled to the processor unit 600. The memory 610 can be any memory described herein or any other memory known to those of skill in the art. The memory 610 can store computer-executable instructions 615 (code) executable by the processor unit 600.

The processor unit comprises front-end logic 620 that receives instructions from the memory 610. An instruction can be processed by one or more decoders 630. The decoder 630 can generate as its output a micro-operation such as a fixed width micro operation in a predefined format, or generate other instructions, microinstructions, or control signals, which reflect the original code instruction. The front-end logic 620 further comprises register renaming logic 635 and scheduling logic 640, which generally allocate resources and queues operations corresponding to converting an instruction for execution.

The processor unit 600 further comprises execution logic 650, which comprises one or more execution units (EUs) 665-1 through 665-N. Some processor unit embodiments can include a number of execution units dedicated to specific functions or sets of functions. Other embodiments can include only one execution unit or one execution unit that can perform a particular function. The execution logic 650 performs the operations specified by code instructions. After completion of execution of the operations specified by the code instructions, back-end logic 670 retires instructions using retirement logic 675. In some embodiments, the processor unit 600 allows out of order execution but requires in-order retirement of instructions. Retirement logic 675 can take a variety of forms as known to those of skill in the art (e.g., re-order buffers or the like).

The processor unit 600 is transformed during execution of instructions, at least in terms of the output generated by the decoder 630, hardware registers and tables utilized by the register renaming logic 635, and any registers (not shown) modified by the execution logic 650.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is a computing system, comprising: a cooling apparatus comprising: a casing comprising a first wall and a second wall; an inner wall; a fluid input; a fluid output; a first chamber connected to the fluid input and the fluid output, the first chamber enclosed in part by the first wall and the inner wall; and a vapor chamber comprising a two-phase fluid, the vapor chamber enclosed in part by the inner wall and the second wall; and an integrated circuit component attached to the second wall of the cooling apparatus, the integrated circuit component comprising a plurality of integrated circuit dies.

Example 2 comprises the computing system of Example 1, wherein the integrated circuit dies are arranged along an axis extending from the fluid input to the fluid output, a first one of the integrated circuit dies being located further along the axis from the fluid input than a second one of the integrated circuit dies.

Example 3 comprises the computing system of Example 1 or 2, wherein the vapor chamber comprises one or more wicks located on one or more faces of the vapor chamber.

Example 4 comprises the computing system of any one of Examples 1-3, wherein a lateral boundary of the vapor chamber encompasses an outer boundary of individual of the integrated circuit dies.

Example 5 comprises the computing system of any one of Examples 1-4, wherein a lateral boundary of the first chamber encompasses an outer boundary of individual of the integrated circuit dies.

Example 6 comprises the computing system of any one of Examples 1-5, wherein the computing system further comprises one or more passive electronic components and a lateral boundary of the vapor chamber encompasses an outer boundary of individual of the passive electronic components and individual of the integrated circuit component.

Example 7 comprises the computing system of any one of Examples 1-6, wherein the integrated circuit component is a first integrated circuit component and the integrated circuit dies are first integrated circuit dies, the computing system further comprising a second integrated circuit component attached to the second wall of the cooling apparatus, the second integrated circuit component comprising a second plurality of integrated circuit dies.

Example 8 comprises the computing system of Example 7, wherein a lateral boundary of the vapor chamber encompasses an outer boundary of individual of the first integrated circuit dies and individual of the second integrated circuit dies.

Example 9 comprises the computing system of any one of Examples 1-8, further comprising a printed circuit board, the integrated circuit component physically coupled to the printed circuit board.

Example 10 comprises the computing system of any one of Examples 1-9, further comprising: a heat exchanger; one or more conduits arranged to create a loop comprising the heat exchanger and the cooling apparatus; and a pump to circulate a cooling liquid through the loop.

Example 11 comprises the computing system of Example 10, further comprising a housing containing the integrated circuit component, the cooling apparatus, the heat exchanger, and the pump.

Example 12 comprises the computing system of Example 10, further comprising a housing, wherein the integrated circuit component and the cooling apparatus are contained within the housing and the heat exchanger and the pump are located external to the housing.

Example 13 is a cooling apparatus comprising: a casing comprising a first wall and a second wall; an inner wall; a fluid input; a fluid output; a first chamber connected to the fluid input and the fluid output, the first chamber enclosed in part by the first wall and the inner wall; and a vapor chamber comprising a two-phase fluid, the vapor chamber enclosed in part by the inner wall and the second wall.

Example 14 comprises the cooling apparatus of Example 13, wherein there is no thermal interface material layer between the first chamber and the vapor chamber.

Example 15 comprises the cooling apparatus of Example 13 or 14, wherein the vapor chamber comprises one or more wicks located on one or more faces of the vapor chamber.

Example 16 is a method comprising: operating a first integrated circuit die of a plurality of integrated circuit dies at a first power consumption level; and operating a second integrated circuit die of the integrated circuit dies at a second power consumption level, the integrated circuit dies located within an integrated circuit component attached to a cooling apparatus, the cooling apparatus comprising: a casing comprising a first wall and a second wall, the integrated circuit component attached to the second wall; an inner wall; a fluid input; a fluid output; a first chamber connected to the fluid input and the fluid output, the first chamber enclosed in part by the first wall and the inner wall; and a vapor chamber comprising a two-phase fluid, the vapor chamber enclosed in part by the inner wall and the second wall.

Example 17 comprises the method of Example 16, further comprising pumping a cooling liquid through the cooling apparatus.

Example 18 comprises the method of Example 16 or 17, further comprising pumping the cooling liquid through one or more conduits, a heat exchanger, and a pump; the conduits, the heat exchanger, the pump, and the cooling apparatus arranged to create a loop.

Example 19 comprises the method of any one of Examples 16-18, wherein the integrated circuit dies are arranged along an axis extending from the fluid input to the fluid output, the first integrated circuit die located further along the axis from the fluid input than the second integrated circuit die.

Example 20 comprises the method of any one of Examples 16-19, wherein a lateral boundary of the vapor chamber encompasses an outer boundary of the first integrated circuit die and an outer boundary of the second integrated circuit die.

Example 21 comprises the method of Example 16, wherein a lateral boundary of the first chamber encompasses an outer boundary of the first integrated circuit die and an outer boundary of the second integrated circuit die.

Example 22 is a computing system, comprising: an integrated circuit component comprising one or more integrated circuit dies; and a cooling means to cooling the integrated circuit dies and substantially equalize a temperature of individual of the integrated circuit dies during operation of the integrated circuit dies.

Example 23 comprises the computing system of Example 22, wherein the integrated circuit component is a first integrated circuit component and the integrated circuit dies are first integrated circuit dies, the computing system further comprising a second integrated circuit component comprising a second plurality of integrated circuit dies, the cooling means to further cool the second integrated circuit dies and substantially equalize the temperature of individual of the first integrated circuit dies and a temperature of individual of the second integrated circuit dies during operation of the first integrated circuit dies and the second integrated circuit dies.

1. A computing system, comprising:
a cooling apparatus comprising:
a casing comprising a first wall and a second wall;
an inner wall;
a fluid input;
a fluid output;
a first chamber connected to the fluid input and the fluid output, the first chamber enclosed in part by the first wall and the inner wall; and
a vapor chamber comprising a two-phase fluid, the vapor chamber enclosed in part by the inner wall and the second wall; and
an integrated circuit component attached to the second wall of the cooling apparatus, the integrated circuit component comprising a plurality of integrated circuit dies.

2. The computing system of claim 1, wherein the integrated circuit dies are arranged along an axis extending from the fluid input to the fluid output, a first one of the integrated circuit dies being located further along the axis from the fluid input than a second one of the integrated circuit dies.

3. The computing system of claim 1, wherein a lateral boundary of the vapor chamber encompasses an outer boundary of individual of the integrated circuit dies.

4. The computing system of claim 1, wherein the vapor chamber comprises one or more wicks located on one or more faces of the vapor chamber.

5. The computing system of claim 1, wherein a lateral boundary of the first chamber encompasses an outer boundary of individual of the integrated circuit dies.

6. The computing system of claim 1, wherein the computing system further comprises one or more passive electronic components and a lateral boundary of the vapor chamber encompasses an outer boundary of individual of the passive electronic components and individual of the integrated circuit component.

7. The computing system of claim 1, wherein the integrated circuit component is a first integrated circuit component and the integrated circuit dies are first integrated circuit dies, the computing system further comprising a second integrated circuit component attached to the second wall of the CPVC, the second integrated circuit component comprising a second plurality of integrated circuit dies.

8. The computing system of claim 7, wherein a lateral boundary of the vapor chamber encompasses an outer boundary of individual of the first integrated circuit dies and individual of the second integrated circuit dies.

9. The computing system of claim 1, further comprising a printed circuit board, the integrated circuit component physically coupled to the printed circuit board.

10. The computing system of claim 1, further comprising:
a heat exchanger;
one or more conduits arranged to create a loop comprising the heat exchanger and the CPVC; and
a pump to circulate a cooling liquid through the loop.

11. The computing system of claim 10, further comprising a housing containing the integrated circuit component, the CPVC, the heat exchanger, and the pump.

12. The computing system of claim 10, further comprising a housing, wherein the integrated circuit component and the CPVC are contained within the housing and the heat exchanger and the pump are located external to the housing.

13. A cooling apparatus comprising:
a casing comprising a first wall and a second wall;
an inner wall;
a fluid input;
a fluid output;
a first chamber connected to the fluid input and the fluid output, the first chamber enclosed in part by the first wall and the inner wall; and
a vapor chamber comprising a two-phase fluid, the vapor chamber enclosed in part by the inner wall and the second wall.

14. The cooling apparatus of claim 13, wherein there is no thermal interface material layer between the first chamber and the vapor chamber.

15. The cooling apparatus of claim 13, wherein the vapor chamber comprises one or more wicks located on one or more faces of the vapor chamber.

16. A method comprising:
operating a first integrated circuit die of a plurality of integrated circuit dies at a first power consumption level; and
operating a second integrated circuit die of the integrated circuit dies at a second power consumption level, the integrated circuit dies located within an integrated circuit component attached to a cooling apparatus, the cooling apparatus comprising:
a casing comprising a first wall and a second wall, the integrated circuit component attached to the second wall;
an inner wall;
a fluid input;
a fluid output;
a first chamber connected to the fluid input and the fluid output, the first chamber enclosed in part by the first wall and the inner wall; and
a vapor chamber comprising a two-phase fluid, the vapor chamber enclosed in part by the inner wall and the second wall.

17. The method of claim 16, further comprising pumping a cooling liquid through the cooling apparatus.

18. The method of claim 17, further comprising pumping the cooling liquid through one or more conduits, a heat exchanger, and a pump; the conduits, the heat exchanger, the pump, and the cooling apparatus arranged to create a loop.

19. The method of claim 16, wherein the integrated circuit dies are arranged along an axis extending from the fluid input to the fluid output, the first integrated circuit die located further along the axis from the fluid input than the second integrated circuit die.

20. The method of claim 16, wherein a lateral boundary of the vapor chamber encompasses an outer boundary of the first integrated circuit die and an outer boundary of the second integrated circuit die.

21. The method of claim 16, wherein a lateral boundary of the first chamber encompasses an outer boundary of the first integrated circuit die and an outer boundary of the second integrated circuit die.

22. A computing system, comprising:
an integrated circuit component comprising one or more integrated circuit dies; and
a cooling means to cooling the integrated circuit dies and substantially equalize a temperature of individual of the integrated circuit dies during operation of the integrated circuit dies.

23. The computing system of claim 22, wherein the integrated circuit component is a first integrated circuit component and the integrated circuit dies are first integrated circuit dies, the computing system further comprising a second integrated circuit component comprising a second plurality of integrated circuit dies, the cooling means to further cool the second integrated circuit dies and substantially equalize the temperature of individual of the first integrated circuit dies and a temperature of individual of the second integrated circuit dies during operation of the first integrated circuit dies and the second integrated circuit dies.
